(19) United States
(12) Patent Application Publication
(10) Pub. No.: US 2010/0194378 A1
(43) Pub. Date: Aug. 5, 2010

(54) SYSTEM FOR PHASE IDENTIFICATION

(76) Inventors: Jin Gon Kim, Seoul (KR); Jeung Sik Sin, Seoul (KR)

Correspondence Address: JORDAN AND HAMBURG LLP, 122 EAST 42ND STREET, SUITE 4000, NEW YORK, NY, 10168, US

(21) Appl. No.: 12/670,901

(22) PCT Filed: Jul. 23, 2008
(86) PCT No.: PCT/KR08/04319

§ 371 Date: Jan. 27, 2010

(30) Foreign Application Priority Data
Jul. 27, 2007 (KR) 10-2007-0075619

(51) Int. Cl. H03D 13/00

(52) U.S. Cl. 324/76.77

(57) ABSTRACT

A phase identification system for identifying the phase of an extra-high- voltage or low-voltage power distribution line is disclosed. The phase identification system compares a reference phase of a transformer substation with a phase of a power distribution line remote from the transformer substation and identifies the phase. The phase identification system includes a reference unit capturing the reference phase from the transformer substation and transmitting the reference phase to a service server, the service server storing the reference phase received from the reference unit for 30 to 60 minutes and externally transmitting the reference phase via a network, the network providing a data communication path between the service server and a local unit, and the local unit capturing the phase from the power distribution line, receiving the reference phase from the service server, and identifying the phase captured from the power distribution line.

### TECHNICAL FIELD

The present invention relates to a phase identification system, and more particularly to a system for identifying the phase of an extra-high-voltage or low-voltage power distribution line.

### BACKGROUND ART

A power distribution line for supplying power generated in a power station to buildings, factories or home via a transformer substation has a voltage of 22.9 KV or less in Korea.

At this time, the power distribution line has three phases. As known to those skilled in the art, the power distribution line having the three phases should be connected between the lines of a supply side and a use side so as to be matched to the phases thereof.

This is because, the reliability of power supply is improved and the inconvenience in the measurement of load current for improving a load imbalance is solved by reducing the electric loss due to a current imbalance and the stoppage of power supply due to the operation of a relay according to the load imbalance of the use side in view of the supply side, and the quality of a product can be improved and the life span of an apparatus can be increased by using power having excellent quality in view of the use side.

In order to connect the three-phase power distribution line so as to be matched to the phases thereof, the phases of the lines are matched while tracking the line. However, in lines mounted in a big city or subterranean lines, which have complicate configurations, the matching of the phases is inconvenient.

In order to solve a problem which occurs due to a method of manually identifying three phases, an apparatus for checking the phase information of two points which are spaced apart from each other via a wired/wireless communication device is suggested.

However, in such an apparatus, since workers residing at a transformer substation and a point in which the distribution line is mounted transmit/receive the phase information via the wired/wireless communication device whenever the phase information is checked, cost consumed for communication and the management of the workers is excessive.

Since an operation for correcting a phase difference due to a time difference in the communication between the transmitter and the receiver is further required, this apparatus is inconvenient.

In order to solve such a problem, the present applicant suggests a phase identification apparatus for generating a reference clock using a global positioning system (GPS), synchronizing the phases on the basis of the reference clock, and measuring the three phases.

In the existing phase identification apparatus, the phase of the power distribution line is identified after a reference phase waveform capturing unit captures a reference phase from the transformer substation for a predetermined period of time. If the frequency is accurately maintained at 60 Hz, no problem occurs, but, if a slight error (e.g., ±0.1 Hz per hour) occurs and a period from a phase capturing time to a phase identification time is large, it is difficult to accurately identify the phase.

In order to capture the phase information using the reference phase waveform capturing unit and the phase identification system, the reference phase waveform capturing unit or the phase identification apparatus should be connected to a measurement rod. In this case, a safety device should be further included in order to prevent an electric shock.

Since the reference phase waveform capturing unit and the phase identification apparatus should be fixedly mounted in the transformer substation or the power distribution line, portability or application of the apparatus deteriorates.

### DISCLOSURE

### Technical Problem

Therefore, the present invention has been made in view of the above problems, and it is an object of the present invention to provide a phase identification system which is capable of accurately measuring three phases in real time by a signal of a communication network when a power distribution line is mounted or a load imbalance is corrected.

It is another object of the present invention to provide a technology which is capable of improving portability or application of an apparatus by transmitting captured phase information by wireless communication.

### Technical Solution

In accordance with the present invention, the above and other objects can be accomplished by the provision of A phase identification system which compares a reference phase of a transformer substation with a phase of a power distribution line remote from the transformer substation and identifies the phase, the system including: a reference unit capturing the reference phase from the transformer substation and transmitting the reference phase to a service server; the service server storing the reference phase received from the reference unit for 30 to 60 minutes and externally transmitting the reference phase via a network; the network providing a data communication path between the service server and a local unit; and the local unit capturing the phase from the power distribution line, receiving the reference phase from the service server, and identifying the phase captured from the power distribution line.

In the present invention, the network may include at least one or two of the Internet, a wired telephone network and a wireless telephone network.

In the present invention, the reference unit may include a transformer transforming the voltage of the transformer substation to 6 to 15 V; a filter eliminating noise included in an output signal of the transformer; an A/D converter converting an output signal of the filter into a digital signal.; a global positioning system (GPS) receiver receiving positional information and time information from a GPS satellite signal; a controller measuring a phase signal converted by the A/D converter on the basis of one pulse per second (1 PPS) received from the GPS receiver; and a communication unit transmitting data measured by the controller to the service server.

In the present invention, the local unit may include a phase capture unit capturing the phase from the power distribution line and externally transmitting the phase; and an identification unit comparing the phase captured by the phase capture unit with the reference phase captured by the reference unit.

In the present invention, the phase capture unit may include a measurement rod capturing the phase from the power distribution line; and a wired/wireless transmitter externally transmitting the phase captured by the measurement rod.

In the present invention, the wired/wireless transmitter may transmit the captured phase in the form of a sine wave.

In the present invention, the identification unit may include a wired/wireless receiver receiving the captured phase from the phase capture unit; a filter eliminating noise included in an output signal of the wired/wireless receiver; an A/D converter converting an output signal of the filter into a digital signal; a GPS receiver receiving positional information and time information from a GPS satellite signal; a telephone communication unit accessing the service server via the network and receiving the reference phase stored in the service server; an input unit allowing a user to input a command; a processor combining an output signal of the GPS receiver to an output signal of the A/D converter, receiving the reference phase corresponding to a time included in the combined data from the telephone communication unit, performing comparison, and identifying three-phase information; a memory storing the phase combined by the processor and storing the reference phase received via the telephone communication unit; and a display unit displaying the result of identifying the three-phase information by the processor.

In the present invention, the display unit may display sine waves of the reference phase and the captured phase and a vector screen together.

In the present invention, the identification unit may further include a printer printing the result of identifying the three-phase information by the processor.

### Advantageous Effects

According to the present invention, it is possible to provide a phase identification system which is capable of allowing an operator to identify the phase of a power distribution line remote from a transformer substation using a wired and/or wireless telephone signal, being conveniently used, and being readily maintained and repaired.

### DESCRIPTION OF DRAWINGS

The above and other objects, features and other advantages of the present invention will be more clearly understood from the following detailed description taken in conjunction with the accompanying drawings, in which:

FIG. 1 is a block diagram showing a system according to an embodiment of the present invention;

FIG. 2 is a block diagram showing a reference unit according to the embodiment of the present invention; and

FIG. 3 is a block diagram showing a local unit according to the embodiment of the present invention.

### MODE FOR INVENTION

The present invention will now be described more fully with reference to the accompanying drawings, in which exemplary embodiments of the invention are shown.

In describing the present invention, if it is determined that the detailed description of a related known function or construction renders the scope of the present invention unnecessarily ambiguous, the detailed description thereof will be omitted. Meaning of terminology used herein should be determined in consideration of functionality of the present invention, and it may be variable depending on user's or operator's intention, or customs in the art. Therefore, corresponding meaning should be determined with reference to the entire pages of the specification.

### Embodiment

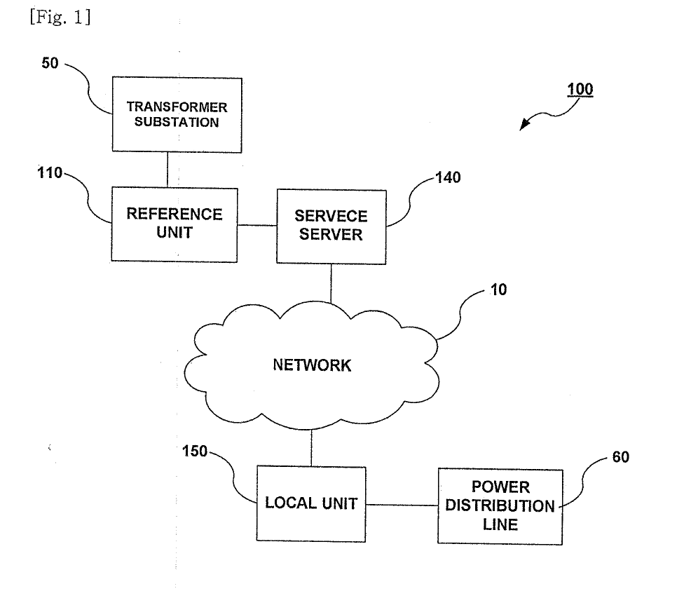

First, a phase identification system according to an embodiment of the present invention will be described with reference to FIGS. 1 to 3.

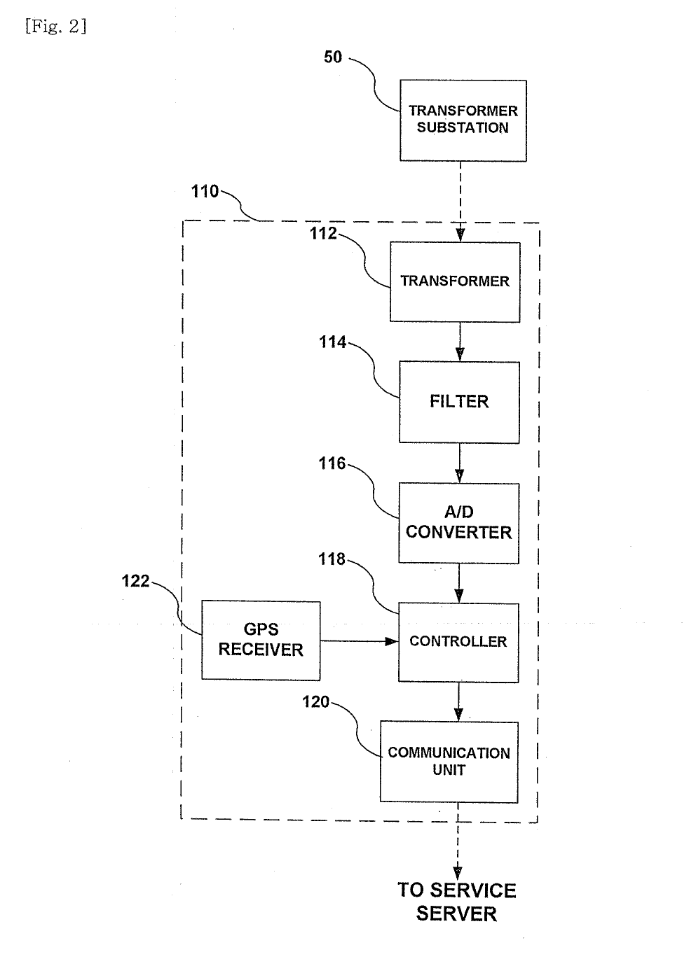

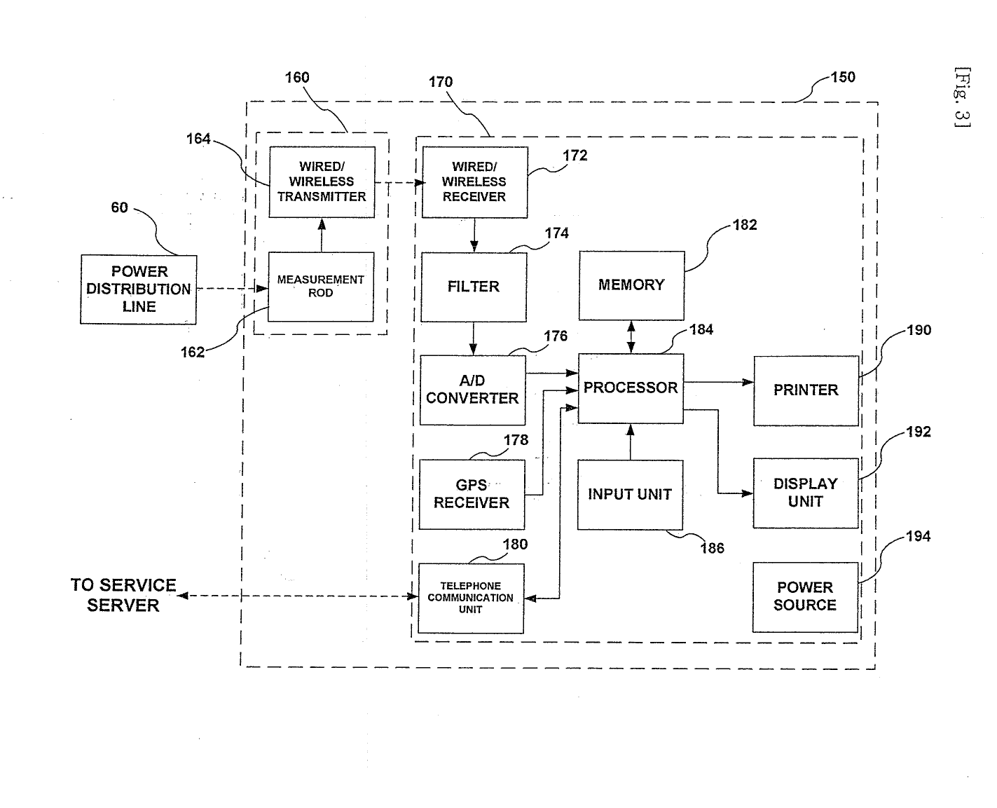

FIG. 1 is a block diagram showing a system according to an embodiment of the present invention, FIG. 2 is a block diagram showing a reference unit according to the embodiment of the present invention, and FIG. 3 is a block diagram showing a local unit according to the embodiment of the present invention.

As shown, the phase identification system 100 (hereinafter, referred to as a “system” for convenience of description) includes a reference unit 110 located between a transformer substation 50 and a power distribution line 60, a service server 140, a network 10, and a local unit 150.

The reference unit 110 captures a reference phase from the transformer substation 50 and transmits the reference phase to the service server 140.

The reference unit 110 will be described in detail with reference to FIG. 2. A transformer 112 transforms the voltage of the transformer substation 50 to 6 to 15 V.

A filter 114 eliminates noise included in an output signal of the transformer 112.

An A/D converter 116 converts an output signal of the filter 114 into a digital signal.

A global positioning system (GPS) receiver 122 receives positional information and time information from a GPS satellite signal.

A controller 118 measures a phase signal converted by the A/D converter 116 on the basis of one pulse per second (1 PPS) received from the GPS receiver 122.

A communication unit 120 transmits the data measured by the controller 118 to the service server.

At this time, the communication unit preferably communicates with the service server 140 on the basis of a RS232 serial communication protocol.

The service server 140 stores the reference phase received from the reference unit 110 for 30 to 60 minutes and externally transmits the reference phase via the network 10.

The network 10 provides a data communication path between the service server 110 and the local unit 150. The network 10 may be configured by at least one or two of the Internet, a wired telephone network, and a wireless telephone network.

The local unit 150 captures the phase from the power distribution line 60, receives the reference phase and identifies the phase captured from the power distribution line 60.

The local unit 150 largely includes a phase capture unit 160 which captures the phase from the power distribution line 60 and an identification unit 170 which compares the phase captured by the phase capture unit 160 with the reference phase captured by the reference unit 110.

The local unit 150 will be described in detail with reference to FIG. 3. A measurement rod 162 of the phase capture unit 160 captures the phase from the power distribution line 60.

A wired/wireless transmitter 164 externally transmits the phase captured by the measurement rod 162. Here, it is preferable that the wired/wireless transmitter 164 transmits the captured phase in the form of a sine wave.

A wired/wireless receiver 172 of the identification unit receives the captured phase from the phase capture unit 160.

A filter 174 eliminates noise included in an output signal of the wired/wireless receiver 172.

An A/D converter 176 converts an output signal of the filter 174 into a digital signal.

A GPS receiver 178 receives the positional information and the time information from the GPS satellite signal.

A telephone communication unit 180 accesses the service server 140 via the network 10 and receives the reference phase stored in the service server 140. It is preferable that the telephone communication unit 180 can operate on the basis of various mobile communication protocols. A mobile communication protocol may be suitably selected by the operation of an input unit 186.

The input unit 186 allows a user to input a command.

A processor 184 combines the output signal of the GPS receiver 178 with the output signal of the A/D converter 176. The processor receives the reference phase corresponding to a time included in the combined data from the telephone communication unit 180, performs comparison, and identifies three-phase information.

A memory 182 stores the reference phase received via the telephone communication unit 180 and the phase combined by the processor 184.

A display unit 192 displays the result of identifying the three-phase information by the processor 184. At this time, it is preferable that the display unit 192 displays the sine waves of the reference phase and the captured phase and a vector screen together.

A printer 190 prints the result of identifying the three-phase information by the processor 184.

### Application Example

Hereinafter, an application example of the system according to the present invention will be described.

In a first step, an A phase, a B phase, a C phase and an N phase are captured from a line of the transformer substation 50 and the voltages are reduced to voltages which can be processed by an electronic circuit of the transformer 112.

In a second step, the controller 118 measures phase data converted by the filter 114 and the A/D converter 116 on the basis of the 1 PPS received from the GPS receiver 122.

In a third step, the signal is transmitted to the service server 140 via the communication unit 120, and the service server 140 stores the reference phase of 30 to 60 minutes.

In a fourth step, the phase of the power distribution line is captured via the measurement rod 162 and is transmitted to the processor 184 via the wired/wireless transmitter 164, the wired/wireless receiver 172, the filter 174 and the A/D converter 176.

In a fifth step, the processor 184 combines this signal with the time information received by the GPS receiver 178.

In a sixth step, the user operates the input unit 186 so as to set the communication protocol of the telephone communication unit 180 and requests the reference phase stored in the third step to the service server 140. At this time, the requested reference phase information becomes the reference phase having the time information corresponding to the time information used in the fifth step.

In a seventh step, the telephone communication unit 180 receives the reference phase, the processor 184 identifies the phase, and the display unit 192 displays the phase. At this time, the identification of the phase information is performed using a known phase identification algorithm. It is preferable that the display unit 192 displays the result of identifying the phase and the rectangular wave of the captured phase.

By the operation of the input unit 186 by the user, the printer 190 may print the position of the power distribution line, operator information indicating the operator of the local unit 150 and the information including a time when the phase is identified by the processor.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A phase identification system which compares a reference phase of a transformer substation with a phase of a power distribution line remote from the transformer substation and identifies the phase, the system comprising:
a reference unit capturing the reference phase from the transformer substation and transmitting the reference phase to a service server;
the service server storing the reference phase received from the reference unit for 30 to 60 minutes and externally transmitting the reference phase via a network;
the network providing a data communication path between the service server and a local unit; and
the local unit capturing the phase from the power distribution line, receiving the reference phase from the service server, and identifying the phase captured from the power distribution line.

2. The system according to claim 1, wherein the network includes at least one or two of the Internet, a wired telephone network and a wireless telephone network.

3. The system according to claim 1, wherein the reference unit includes:
a transformer transforming the voltage of the transformer substation to 6 to 15 V;
a filter eliminating noise included in an output signal of the transformer;
an A/D converter converting an output signal of the filter into a digital signal;
a global positioning system (GPS) receiver receiving positional information and time information from a GPS satellite signal;
a controller measuring a phase signal converted by the A/D converter on the basis of one pulse per second (1 PPS) received from the GPS receiver; and
a communication unit transmitting data measured by the controller to the service server.

4. The system according to claim 1, wherein the local unit includes:
a phase capture unit capturing the phase from the power distribution line and externally transmitting the phase; and
an identification unit comparing the phase captured by the phase capture unit with the reference phase captured by the reference unit.

5. The system according to claim 4, wherein the phase capture unit includes:
a measurement rod capturing the phase from the power distribution line; and
a wired/wireless transmitter externally transmitting the phase captured by the measurement rod.

6. The system according to claim 5, wherein the wired/wireless transmitter transmits the captured phase in the form of a sine wave.

7. The system according to claim 4, wherein the identification unit includes:
a wired/wireless receiver receiving the captured phase from the phase capture unit;
a filter eliminating noise included in an output signal of the wired/wireless receiver;
an A/D converter converting an output signal of the filter into a digital signal;
a GPS receiver receiving positional information and time information from a GPS satellite signal;
a telephone communication unit accessing the service server via the network and receiving the reference phase stored in the service server;
an input unit allowing a user to input a command;
a processor combining an output signal of the GPS receiver to an output signal of the A/D converter, receiving the reference phase corresponding to a time included in the combined data from the telephone communication unit, performing comparison, and identifying three-phase information;
a memory storing the phase combined by the processor and storing the reference phase received via the telephone communication unit; and
a display unit displaying the result of identifying the three-phase information by the processor.

8. The system according to claim 7, wherein the display unit displays sine waves of the reference phase and the captured phase and a vector screen together.

9. The system according to claim 7, wherein the identification unit further includes a printer printing the result of identifying the three-phase information by the processor.
